(19) United States
(12) Patent Application Publication
(10) Pub. No.: US 2009/0130847 A1
(43) Pub. Date: May 21, 2009

(54) METHOD OF FABRICATING METAL PATTERN WITHOUT DAMAGING INSULATION LAYER

(75) Inventors: Hyun-ku Jeong, Hwaseong-si (KR); Seok-gin Kang, Suwon-si (KR); Jin-ho Lee, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: Samsung Electronics Co., Ltd., Suwon-si (KR)

(21) Appl. No.: 12/123,495

(22) Filed: May 20, 2008

(30) Foreign Application Priority Data
Nov. 20, 2007 (KR) 10-2007-0118528

(51) Int. Cl. H01L 21/768

(52) U.S. Cl. 438/674; 257/E21.585

(57) ABSTRACT

Provided is a method of fabricating a metal pattern so that an insulation layer between a wafer and the metal pattern can be prevented from being damaged in a planarization procedure when the metal pattern having a trench structure is fabricated on the wafer. The method includes operations of forming a first insulation layer on a surface of the wafer; selectively etching the surface of the wafer and the first insulation layer so as to form a plurality of trenches; forming a second insulation layer on a bottom and side walls of the plurality of trenches by using a thermal oxidation method; filling a metal inside the plurality of trenches; and performing planarization by removing the metal deposited outside the plurality of trenches.

### CROSS-REFERENCE TO RELATED PATENT APPLICATION

This application claims the benefit of Korean Patent Application No. 10-2007-0118528, filed on Nov. 20, 2007, in the Korean Intellectual Property Office, the disclosure of which is incorporated herein in its entirety by reference.

### BACKGROUND OF THE INVENTION

1. Field of the Invention

The present invention relates to a method of fabricating a metal pattern without damaging an insulation layer, and more particularly, to a method of fabricating a metal pattern so that an insulation layer between a wafer and the metal pattern can be prevented from being damaged in a planarization procedure when the metal pattern having a trench structure is fabricated on the wafer.

2. Description of the Related Art

In general, micro-electro-mechanical systems (MEMS) devices such as a micro-actuator or a micro-scanner can be formed by patterning each of top and bottom silicon wafers of a silicon-on-insulator (SOI) wafer. At this time, a minute metal pattern such as a coil is required to be fabricated on a wafer, so as to detect operations of the micro-actuator and the micro-scanner via feedback sensing.

Such a metal pattern is generally fabricated to have a trench structure, by using a damascene process. The damascene process for fabricating the metal pattern on a wafer commonly includes a procedure of etching a top surface of the wafer so as to form a trench, a procedure of forming an insulation layer on a surface of the wafer and inside the trench, a procedure of filling a metal inside the trench, and a procedure of planarizing a protruding part. Here, various methods of forming the insulation layer are possible. For example, the insulation layer can be formed by directly depositing a SiO₂ layer by using Plasma Enhanced Chemical Vapor Deposition (PECVD), by reacting SiH₄ with O₂ on the wafer at a temperature of 450° C., or by reacting SiCl₂H₂ with N₂O on the wafer at a temperature of 900° C. As another method, the method of forming a silicon oxide film on the wafer by using a tetraethyl orthosilicate (TEOS; Si(C₂H₅O)₄) gas is known. Also, there is a thermal oxidation method by which a silicon wafer is heated and thermally oxidized, thereby forming a SiO₂ layer on the surface of the wafer.

From among the aforementioned methods, the thermal oxidation method is widely used since the thermal oxidation method can form the insulation layer having a uniform thickness on the surface of the wafer and inside the trench, and does not narrow an inner width of the trench. However, in the case of the thermal oxidation method, a deposition time for the insulation layer takes a relatively long time, and the surface of the wafer can be bent or curved due to the high temperature that occurs during an insulation layer deposition procedure or due to stress caused by diffusion of the insulation layer. As a result, after the metal pattern is fabricated, the insulation layer can be damaged in a procedure of planarizing the metal pattern.

### SUMMARY OF THE INVENTION

The present invention provides a method of fabricating a metal pattern so that an insulation layer between a wafer and the metal pattern can be prevented from being damaged when the metal pattern is fabricated on the wafer.

According to an aspect of the present invention, there is provided a method of fabricating a metal pattern, the method including operations of forming a first insulation layer on a surface of a wafer; selectively etching the surface of the wafer and the first insulation layer so as to form a plurality of trenches; forming a second insulation layer on a bottom and side walls of the plurality of trenches by using a thermal oxidation method; filling a metal inside the plurality of trenches; and performing planarization by removing the metal deposited outside the plurality of trenches.

The first insulation layer may be formed so as to have a uniform thickness by using a tetraethyl orthosilicate (TEOS) gas.

The operation of forming the plurality of trenches may include the operations of coating a photoresist on the first insulation layer; patterning the photoresist so as to remove the photoresist from positions in which the plurality of trenches are to be formed; and etching each of the first insulation layer and the wafer by using the photoresist as a mask.

The second insulation layer may be formed by heating the wafer at a temperature of 1000° C. to 1200° C. and by oxidizing an inside of one of the plurality of trenches.

The second insulation layer may be formed on an exterior surface of the first insulation layer and is formed on an interface between the first insulation layer and the wafer.

The operation of performing the planarization may be performed until the second insulation layer formed on the first insulation layer is removed.

The first and second insulation layers may be silicon oxide films.

The metal may be a copper (Cu).

The wafer may be a silicon wafer.

The wafer may be a silicon-on-insulator (SOI) wafer.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view of an example in which a minute metal pattern is fabricated on a wafer; and

FIGS. 2A through 2E are cross-sectional views illustrating a method of fabricating a metal pattern without damaging an insulation layer according to an embodiment of the present invention.

### DETAILED DESCRIPTION OF THE INVENTION

A method of fabricating a metal pattern according to embodiments of the present invention will now be described more fully with reference to the accompanying drawings, in which exemplary embodiments of the invention are shown.

FIG. 1 is a cross-sectional view of an example in which a minute metal pattern 12 is fabricated on a wafer 10. Viewing the example from above, such a metal pattern 12 may be in the shape of a spiral coil or may be formed to have various other shapes according to requirements. In general, a low resistance wafer such as a silicon wafer may be used as the wafer 10. Also, in the case where a micro-electro-mechanical systems (MEMS) scanner or a MEMS actuator is manufactured, the wafer 10 may be a silicon-on-insulator (SOI) wafer (not shown) in which a silicon layer is formed on each of both sides of an insulation layer. In the case where the metal pattern 12 is fabricated on the wafer 10 having a low resistance, an insulation layer 11 has to be formed between the wafer 10 and the metal pattern 12. As described above, various methods of forming the insulation layer 11 are known. However, a method of forming the insulation layer 11 having a uniform thickness between the wafer 10 and the metal pattern 12, without deforming the wafer 10, has not been developed so far.

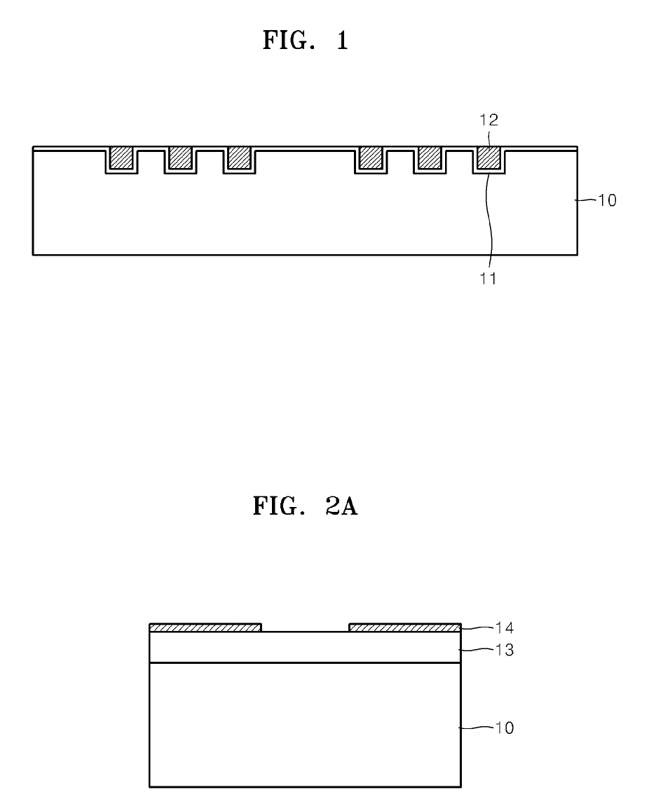

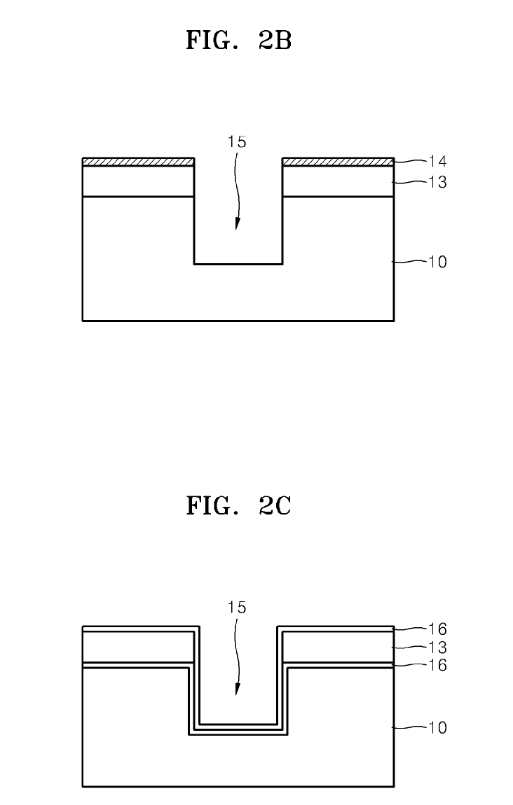

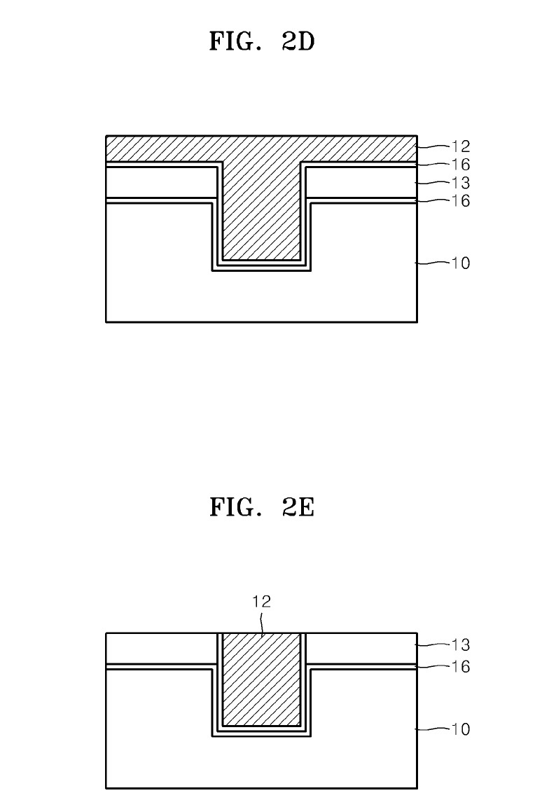

FIGS. 2A through 2E are cross-sectional views for visually describing a method of forming an insulation layer having a uniform thickness on a wafer 10 without damaging the insulation layer and a method of fabricating a metal pattern 12 according to an embodiment of the present invention.

First, referring to FIG. 2A, a first insulation layer 13 having a uniform thickness is formed on the wafer 10, and a photoresist 14 is coated on the first insulation layer 13. Here, the first insulation layer 13 may be formed by using commonly known methods such as a Plasma Enhanced Chemical Vapor Deposition (PECVD) method which was described above. However, the most appropriate method from among the commonly known methods is a method of spilling a tetraethyl orthosilicate (TEOS; Si(C₂H₅O)₄) gas on the wafer 10 so as to form a silicon oxide film on the wafer 10. To be more specific, the silicon oxide film may be formed on the wafer 10 by reacting the TEOS gas with one of O₃ gas and O₂ gas at a temperature of 450° C. in a deposition chamber. In the case where the first insulation layer 13 is formed by using the TEOS gas, the reaction temperature is relatively low so that deformation of the wafer 10 rarely occurs. In particular, the silicon oxide film formed by using the TEOS gas is advantageous in that a total thickness of the silicon oxide film can be uniformly controlled, as described above. In this manner, since the thickness of the first insulation layer 13 is uniform, the metal pattern 12 and the first insulation layer 13 may be prevented from being partially damaged in a planarization procedure to be described later, wherein the planarization procedure occurs after the metal pattern is formed.

Meanwhile, after the photoresist 14 is coated on the first insulation layer 13, the photoresist 14 is patterned according to a shape of the metal pattern 12 to be formed at a later time. As illustrated in FIG. 2A, the photoresist 14 at a position in which a trench 15 (refer to FIG. 2B) is to be formed, is removed by such patterning.

After that, referring to FIG. 2B, by using the photoresist 14 as a mask, the first insulation layer 13 and the wafer 10 are respectively etched by using a wet etching method or a dry etching method. Then, as illustrated in FIG. 2B, the trench 15, into which the metal pattern 12 is to be filled, is formed on the wafer 10.

Next, referring to FIG. 2C, a second insulation layer 16 is formed on a bottom and side walls of the trench 15. The second insulation layer 16 may be formed by using a thermal oxidation method in which the wafer 10 is heated at a temperature of 1000° C. to 1200° C. so that an inside of the trench 15 is oxidized. When an insulation layer is formed by using the thermal oxidation method, the insulation layer formed of a silicon oxide film may be diffused and formed inside a wafer. Thus, in the case of attempting to form the insulation layer having a uniform thickness, the thermal oxidation method may minimize narrowing of the trench 15 due to the formation of the insulation layer, compared to other methods. That is, as illustrated in FIG. 2C, in the case where the second insulation layer 16 is formed by using the thermal oxidation method, the second insulation layer 16 may be formed not only on exterior surfaces of the first insulation layer 13 and the trench 15 but may also penetrate inside the wafer 10 and be formed on an interface between the first insulation layer 13 and the trench 15 and on an inner wall of the trench 15. By doing so, a phenomenon, in which a width of the trench 15 is excessively narrowed, may be prevented, with the second insulation layer 16 being formed so as to have a sufficient thickness inside the trench 15. As a result, an increase in the resistance of the metal pattern 12 (refer to FIG. 2E) which is to be fabricated inside the trench 15, may be minimized.

After that, referring to FIG. 2D, the metal pattern (that is, a metal layer) 12 is filled inside the trench 15 by using general metal vapor deposition methods such as an electroplating method, a sputtering method, or an E-beam evaporation method. In the aforementioned deposition procedure, as illustrated in FIG. 2D, the metal layer 12 is formed not only inside the trench 15 but also is formed on an exterior surface of the second insulation layer 16. Thus, as illustrated in FIG. 2E, a planarization is performed by removing the metal layer 12 which is deposited outside the trench 15, by using a general planarization procedure such as a Chemical Mechanical Polishing (CMP). At this time, when a total thickness of the insulation layer including the first and second insulation layers 13 and 16 is thicker than a desired thickness, the second insulation layer 16 formed on the first insulation layer 13 may also be removed in the planarization procedure.

In this manner, a metal remains only inside the trench 15 so that the metal pattern 12 having a desired pattern may be fabricated according to a shape of the trench 15. For example, in the case where an operation of the MEMS scanner is detected via feedback sensing, in order to sense a moving angle by using a variation in capacitance between each of comb electrodes, insulation between a spiral coil of the metal pattern 12, which is a moving part, and the wafer 10 having the low resistance, is necessarily required. In this case, the metal for fabricating the metal pattern 12 may be copper (Cu). However, according to other embodiments of the present invention, a pattern and a material, which are for the metal pattern 12, may be varied.

According to the present invention, the insulation layer is not formed by using a single procedure but is formed by two divided procedures which are different from each other. Thus, the present invention counterbalances disadvantages that occur when using any one of the two procedures. For example, as described above, in the case where the uniform first insulation layer 15 is first formed by using the TEOS gas and then the second insulation layer 16 is formed by using the thermal oxidation method, a time during which the wafer 10 is exposed to the high temperature can be minimized. Thus, deformation of the wafer 10 and deformation of the insulation layer due to the wafer deformation can be prevented, and also, a total deposition time of the insulation layer can be reduced. In addition, the present invention can prevent the trench 15 from narrowing, thereby preventing an increase in a resistance of the metal pattern 12 to be fabricated. Moreover, the present invention can avoid problems such as a thickness of the metal pattern 12 and a thickness of the insulation layer not being uniform due to roughness of the wafer 10 and the insulation layer when the metal pattern 12 is planarized, or such as the metal pattern 12 and the insulation layer being partially removed.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a metal pattern, the method comprising:
forming a first insulation layer on a surface of a wafer;
selectively etching the surface of the wafer and the first insulation layer so as to form a plurality of trenches;
forming a second insulation layer on a bottom and side walls of the plurality of trenches by using a thermal oxidation method;
filling a metal inside the plurality of trenches; and
performing planarization by removing the metal deposited outside the plurality of trenches.

2. The method of claim 1, wherein the first insulation layer is formed so as to have a uniform thickness by using a TEOS (tetraethyl orthosilicate) gas.

3. The method of claim 1, wherein the forming of the plurality of trenches comprises:
coating a photoresist on the first insulation layer;
patterning the photoresist so as to remove the photoresist from positions in which the plurality of trenches are to be formed; and
etching each of the first insulation layer and the wafer by using the photoresist as a mask.

4. The method of claim 1, wherein the second insulation layer is formed by heating the wafer at a temperature of 1000° C. to 1200° C. and by oxidizing an inside of one of the plurality of trenches.

5. The method of claim 4, wherein the second insulation layer is formed on an exterior surface of the first insulation layer and is formed on an interface between the first insulation layer and the wafer.

6. The method of claim 5, wherein the planarization is performed until the second insulation layer formed on the first insulation layer is removed.

7. The method of claim 1, wherein the first and second insulation layers are silicon oxide films.

8. The method of claim 1, wherein the metal is Cu (copper).

9. The method of claim 1, wherein the wafer is a silicon wafer.

10. The method of claim 1, wherein the wafer is a SOI (silicon-on-insulator) wafer.
